(19) United States
(12) Patent Application Publication
(10) Pub. No.: US 2021/0091819 A1
(43) Pub. Date: Mar. 25, 2021

(54) DYNAMIC SWITCHING OF LOCAL OSCILLATOR SIGNAL FREQUENCY FOR UP-CONVERSION AND DOWN-CONVERSION IN TIME DIVISION DUPLEX WIRELESS COMMUNICATION

(71) Applicant: QUALCOMM Incorporated, San Diego, CA (US)

(72) Inventors: Bhushan Shanti Asuri, San Diego, CA (US); Yiwu Tang, San Diego, CA (US); Shrenik Patel, San Diego, CA (US)

(21) Appl. No.: 16/578,096

(22) Filed: Sep. 20, 2019

(51) Int. Cl. H04B 1/403; H04L 5/14

(52) U.S. Cl. CPC H04B 1/406; H03L 7/0992; H04L 5/1469

(57) ABSTRACT

Wireless communication system may be configured to use different frequency bands for uplink communication and downlink communication. For example, a wireless system may use multiple frequency bands for downlink with carrier aggregation, and the wireless system may use only one frequency band for uplink. Up-conversion and down-conversion between baseband signals and RF signals, using a fixed frequency local oscillator signal may cause energy leak to an adjacent frequency band during transmission of signal and may result in interferences to other radio communication devices using the adjacent bands. To limit the amount of energy that leaks out of its assigned radio frequency bands, the UE may use local oscillator signals with different frequencies for up-conversion and down-conversion and may switch the frequencies of the local oscillator signals between reception of downlink signals and transmission of uplink signals.

### TECHNICAL FIELD

Aspects of the present disclosure relate generally to wireless communication systems, and more particularly, to techniques for dynamically switching local oscillator signal frequencies. Some aspects and/or embodiments can be used for up-conversion from a first baseband signal to a first RF signal and down-conversion from a second RF signal to a second baseband signal via a non-fixed, dynamic oscillator. Utilizing varying oscillator frequency techniques can enable and provide increased system performance, minimize interference, and reduce energy leaks associated with adjacent frequency bands.

### INTRODUCTION

A wireless communication network may include a number of base stations (BS or node Bs) that can support communication for a number of user equipments (UEs). A UE may communicate with a base station via downlink and uplink. The downlink (or forward link) refers to the communication link from the base station to the UE, and the uplink (or reverse link) refers to the communication link from the UE to the base station.

A base station may transmit data and control information on the downlink to a UE and/or may receive data and control information on the uplink from the UE. On the downlink, a transmission from the base station may encounter interference due to transmissions from neighbor base stations or from other wireless radio frequency (RF) transmitters. On the uplink, a transmission from the UE may encounter interference from uplink transmissions of other UEs communicating with the neighbor base stations or from other wireless RF transmitters. This interference may degrade performance on both the downlink and uplink.

Within UE and BS devices, A baseband signal is an original signal that a receiver and a transmitter in wireless communication system process to add or retrieve information. For transmission over the air, a transmitter converts a baseband signal frequency into a RF signal with higher frequency by mixing the baseband signal with a local oscillator signal with a high frequency. This process is called as direct up-conversion. Similarly, a receiver can convert received RF signals into baseband signals by mixing the RF signal with the local oscillator signal. This process is called as direct down-conversion.

As the demand for mobile broadband access continues to increase, the possibilities of interference and congested networks grows with more UEs accessing the long-range wireless communication networks and more short-range wireless systems being deployed in communities. Research and development continue to advance wireless technologies not only to meet the growing demand for mobile broadband access, but to advance and enhance the user experience with mobile communications.

### SUMMARY

The following summarizes some aspects of the present disclosure to provide a basic understanding of the discussed technology. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure in summary form as a prelude to the more detailed description that is presented later.

In a typical time division duplex (TDD) wireless system where the uplink and downlink are separated by allocation of different time slots in the same frequency band, a UE may use a fixed frequency of a local oscillator signal for both up-conversion and down-conversion. Yet, a new generation of TDD wireless communication system may be configured to use different frequency bands for uplink communication and downlink communication. For example, and as discussed below according to aspects, a wireless system may use multiple frequency bands for downlink with carrier aggregation while the wireless system may use only one frequency band for uplink. Using a fixed (non-dynamic) frequency for a local oscillator signal for both up-conversion and down-conversion may cause energy leak to an adjacent frequency band.

Also, interferences with other radio communication devices using adjacent bands may be experienced. In an aspect, to limit or minimize of energy that leaks out of its assigned radio frequency bands, a UE may be configured to switch frequencies of local oscillator signals.

Dynamic switching of oscillator frequency signals may occur during up-conversion and down-conversion between reception of downlink signal and transmission of uplink signal.

In one aspect of the disclosure, a wireless terminal in TDD system is disclosed. Generally, a wireless terminal may include a variety of circuits, including receiver circuitry and transmitter circuitry. The wireless terminal may include a receiver circuit configured to down-convert a first radio frequency (RF) signal received by the wireless terminal during a TDD downlink timeslot of a TDD frame into a first baseband signal. Down conversion can use a first local oscillator signal from a local oscillator signal source (e.g., an oscillator in the wireless terminal). The wireless terminal may also include a transmitter circuit configured to upconvert a second baseband signal into a second RF signal to transmit to a base station during a TDD uplink timeslot of the TDD frame using a second local oscillator signal from the local oscillator signal source.

In an additional aspect of the disclosure, a method for TDD wireless communication is disclosed. The method may include down-converting, by a receiver circuit of a wireless terminal, a first RF signal received by the wireless terminal during a TDD downlink timeslot of a TDD frame into a first baseband signal. Down conversion can use a first local oscillator signal from a local oscillator signal source (e.g., an oscillator in the wireless terminal). The method may also include upconverting, by a transmitter circuit of the wireless terminal, a second baseband signal into a second RF signal to transmit to a base station during a TDD uplink timeslot of the TDD frame using a second local oscillator signal from the local oscillator signal source.

In an additional aspect of the disclosure, an article of manufacture may include a non-transitory computer-readable medium having stored therein instructions by a processor of a wireless terminal in TDD wireless communication. The instructions may cause the processor to provide a first local oscillator signal from a local oscillator signal source to down-convert a first RF signal received by the wireless terminal during a TDD downlink timeslot of a TDD frame into a first baseband signal. The instructions may cause the processor to provide a second local oscillator signal from the local oscillator signal source to upconvert a second baseband signal into a second RF signal to transmit to a base station during a TDD uplink timeslot of the TDD frame.

In an additional aspect of the disclosure, an apparatus of a wireless terminal in TDD wireless communication is disclosed. The apparatus may include means for down-converting a first RF signal received by the wireless terminal during a TDD downlink timeslot of a TDD frame into a first baseband signal using a first local oscillator signal from a local oscillator signal source.

The apparatus may further include means for upconverting a second baseband signal into a second RF signal to transmit to a base station during a TDD uplink timeslot of the TDD frame using a second local oscillator signal from the local oscillator signal source.

In some examples of the method, the apparatuses, and the article including non-transitory computer-readable medium described herein, the first RF signal may comprise a plurality of non-contiguous radio frequency bands and a frequency of the first local oscillator signal may be between center frequencies of the plurality of non-contiguous radio frequency bands, and the second RF signal may comprise a single frequency band and a frequency of the second local oscillator signal may be within the single frequency band of the second RF signal.

In some examples of the method, the apparatuses, and the article including non-transitory computer-readable medium described herein, the first RF signal in the plurality of non-contiguous radio frequency bands may be configured with non-contiguous carrier aggregation (NC-CA).

In some examples of the method, the apparatuses, and the article including non-transitory computer-readable medium described herein, the single frequency band of the second RF signal may correspond to one of the plurality of non-contiguous radio frequency bands of the first local oscillator signal.

In some examples of the method, the apparatuses, and the article including non-transitory computer-readable medium described herein, the local oscillator signal source may comprise a frequency synthesizer coupled to the receiver circuit and the transmitter circuit, generating the first local oscillator signal and the second local oscillator signal.

In some examples of the method, the apparatuses, and the article including non-transitory computer-readable medium described herein, the frequency synthesizer may comprise a phase locked loop (PLL) and a frequency divider.

In some examples of the method, the apparatuses, and the article including non-transitory computer-readable medium described herein, the frequency synthesizer may switch between generation of the first local oscillator signal and generation of the second local oscillator signal by changing frequency of signals generated by the PLL.

In some examples of the method, the apparatuses, and the article including non-transitory computer-readable medium described herein, the frequency synthesizer may switch between generation of the first local oscillator signal and generation of the second local oscillator signal by changing configuration of the frequency divider.

In some examples of the method, the apparatuses, and the article including non-transitory computer-readable medium described herein, the frequency synthesizer may switch from generation of the first local oscillator signal to generation of the second local oscillator signal between reception of the first RF signal and transmission of the second RF signal. The frequency synthesizer may also switch from generation of the second local oscillator signal to generation of the first local oscillator signal between transmission of the second RF signal and reception of a second instance of the first RF signal.

In some examples of the method, the apparatuses, and the article including non-transitory computer-readable medium described herein, a controller may be configured to provide a control signal to the local oscillator signal source controlling switching between the first local oscillator signal and the second local oscillator signal.

In some examples of the method, the apparatuses, and the article including non-transitory computer-readable medium described herein, the features described above may be combined in any combinations.

### BRIEF DESCRIPTION OF THE DRAWINGS

A further understanding of the nature and advantages of the present disclosure may be realized by reference to the following drawings. In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

FIG. 1 is a block diagram illustrating details of a wireless communication system.

FIG. 2 is a block diagram illustrating a design of a base station and a UE configured according to one aspect of the present disclosure.

FIG. 3 is a block diagram illustrating an example circuit of a wireless device for up-conversion and down-conversion in accordance with aspects of the present disclosure.

FIG. 4 is a diagram graphically illustrating an example configuration of frequency band allocation of a communication link in a time division duplex (TDD) system using a fixed frequency for a local oscillator signal for both up-conversion and down-conversion according to aspects of the present disclosure.

FIG. 5 is a diagram graphically illustrating an example configuration of frequency band allocation of a communication link in a TDD system with a dynamic switching of frequencies for a local oscillator signal in accordance with aspects of the present disclosure.

FIG. 6 is a diagram graphically illustrating another example of frequency band allocation of a communication link in a TDD system with a dynamic switching of frequencies for a local oscillator signal according to aspects of the present disclosure.

FIG. 7 is a flow diagram illustrating example blocks executed at a UE for dynamic switching of local oscillator signal frequency for up-conversion and down-conversion according to aspects of the present disclosure.

### DETAILED DESCRIPTION

Wireless communication generally involves exchanging a variety of signals at varying frequencies to convey information. Transmission of signals over the air (e.g., via a wireless air channel) uses radio frequency signals while transmitting signals within a device (e.g., in a smartphone) uses baseband frequency signals. Efficient conversions or switching between multiple frequency ranges (e.g., RF and baseband frequency ranges) can help to improve user experience, yield efficient communication, and conserve limited power resources. This disclosure relates generally to dynamically switching frequencies of local oscillator signals (e.g., on oscillator in a communication device). Switching can occur in various manners: up-conversion from a first baseband signal to a first RF signal for transmission; and down-conversion from a second RF signal to a second baseband signal for reception. In some respects, dynamic switching can occur in a TDD wireless communication system.

The detailed description set forth below, in connection with the appended drawings and appendix, is intended as a description of various configurations and is not intended to limit the scope of the disclosure. Rather, the detailed description includes specific details for the purpose of providing a thorough understanding of the inventive subject matter. It will be apparent to those skilled in the art that these specific details are not required in every case and that, in some instances, well-known structures and components are shown in block diagram form for clarity of presentation.

This disclosure relates generally to providing or participating in authorized shared access between two or more wireless communications systems, also referred to as wireless communications networks. In various embodiments, the techniques and apparatus may be used for wireless communication networks such as code division multiple access (CDMA) networks, time division multiple access (TDMA) networks, frequency division multiple access (FDMA) networks, orthogonal FDMA (OFDMA) networks, single-carrier FDMA (SC-FDMA) networks, LTE networks, GSM networks, 5^{th} Generation (5G) or new radio (NR) networks, as well as other communications networks. As described herein, the terms “networks” and “systems” may be used interchangeably.

An OFDMA network may implement a radio technology such as evolved UTRA (E-UTRA), IEEE 802.11, IEEE 802.16, IEEE 802.20, flash-OFDM and the like. UTRA, E-UTRA, and Global System for Mobile Communications (GSM) are part of universal mobile telecommunication system (UMTS). In particular, long term evolution (LTE) is a release of UMTS that uses E-UTRA. UTRA, E-UTRA, GSM, UMTS and LTE are described in documents provided from an organization named “3^{rd} Generation Partnership Project” (3GPP), and cdma2000 is described in documents from an organization named “3^{rd} Generation Partnership Project 2” (3GPP2). These various radio technologies and standards are known or are being developed. For example, the 3^{rd} Generation Partnership Project (3GPP) is a collaboration between groups of telecommunications associations that aims to define a globally applicable third generation (3G) mobile phone specification. 3GPP long term evolution (LTE) is a 3GPP project which was aimed at improving the universal mobile telecommunications system (UMTS) mobile phone standard. The 3GPP may define specifications for the next generation of mobile networks, mobile systems, and mobile devices. The present disclosure is concerned with the evolution of wireless technologies from LTE, 4G, 5G, NR, and beyond with shared access to wireless spectrum between networks using a collection of new and different radio access technologies or radio air interfaces.

In particular, 5G networks contemplate diverse deployments, diverse spectrum, and diverse services and devices that may be implemented using an OFDM-based unified, air interface. In order to achieve these goals, further enhancements to LTE and LTE-A are considered in addition to development of the new radio technology for 5G NR networks. The 5G NR will be capable of scaling to provide coverage (1) to a massive Internet of things (IoTs) with an ultra-high density (e.g., ˜1M nodes/km²), ultra-low complexity (e.g., ˜10s of bits/sec), ultra-low energy (e.g., ˜10+ years of battery life), and deep coverage with the capability to reach challenging locations; (2) including mission-critical control with strong security to safeguard sensitive personal, financial, or classified information, ultra-high reliability (e.g., ˜99.9999% reliability), ultra-low latency (e.g., ˜1 ms), and users with wide ranges of mobility or lack thereof; and (3) with enhanced mobile broadband including extreme high capacity (e.g., ˜10 Tbps/km²), extreme data rates (e.g., multi-Gbps rate, 100+ Mbps user experienced rates), and deep awareness with advanced discovery and optimizations.

The 5G NR may be implemented to use optimized OFDM-based waveforms with scalable numerology and transmission time interval (TTI); having a common, flexible framework to efficiently multiplex services and features with a dynamic, low-latency time division duplex (TDD)/frequency division duplex (FDD) design; and with advanced wireless technologies, such as massive multiple input, multiple output (MIMO), robust millimeter wave (mmWave) transmissions, advanced channel coding, and device-centric mobility. Scalability of the numerology in 5G NR, with scaling of subcarrier spacing, may efficiently address operating diverse services across diverse spectrum and diverse deployments. For example, in various outdoor and macro coverage deployments of less than 3 GHz FDD/TDD implementations, subcarrier spacing may occur with 15 kHz, for example over 1, 5, 10, 20 MHz, and the like bandwidth. For other various outdoor and small cell coverage deployments of TDD greater than 3 GHz, subcarrier spacing may occur with 30 kHz over 80/100 MHz bandwidth. For other various indoor wideband implementations, using a TDD over the unlicensed portion of the 5 GHz band, the subcarrier spacing may occur with 60 kHz over a 160 MHz bandwidth. Finally, for various deployments transmitting with mmWave components at a TDD of 28 GHz, subcarrier spacing may occur with 120 kHz over a 500 MHz bandwidth.

The scalable numerology of the 5G NR facilitates scalable TTI for diverse latency and quality of service (QoS) requirements. For example, shorter TTI may be used for low latency and high reliability, while longer TTI may be used for higher spectral efficiency. The efficient multiplexing of long and short TTIs to allow transmissions to start on symbol boundaries. 5G NR also contemplates a self-contained integrated subframe design with uplink/downlink scheduling information, data, and acknowledgement in the same subframe. The self-contained integrated subframe supports communications in unlicensed or contention-based shared spectrum, adaptive uplink/downlink that may be flexibly configured on a per-cell basis to dynamically switch between uplink and downlink to meet the current traffic needs.

Various other aspects and features of the disclosure are further described below. It should be apparent that the teachings herein may be embodied in a wide variety of forms and that any specific structure, function, or both being disclosed herein is merely representative and not limiting. Based on the teachings herein one of an ordinary level of skill in the art should appreciate that an aspect disclosed herein may be implemented independently of any other aspects and that two or more of these aspects may be combined in various ways. For example, an apparatus may be implemented or a method may be practiced using any number of the aspects set forth herein. In addition, such an apparatus may be implemented or such a method may be practiced using other structure, functionality, or structure and functionality in addition to or other than one or more of the aspects set forth herein. For example, a method may be implemented as part of a system, device, apparatus, and/or as instructions stored on a computer readable medium for execution on a processor or computer. Furthermore, an aspect may comprise at least one element of a claim.

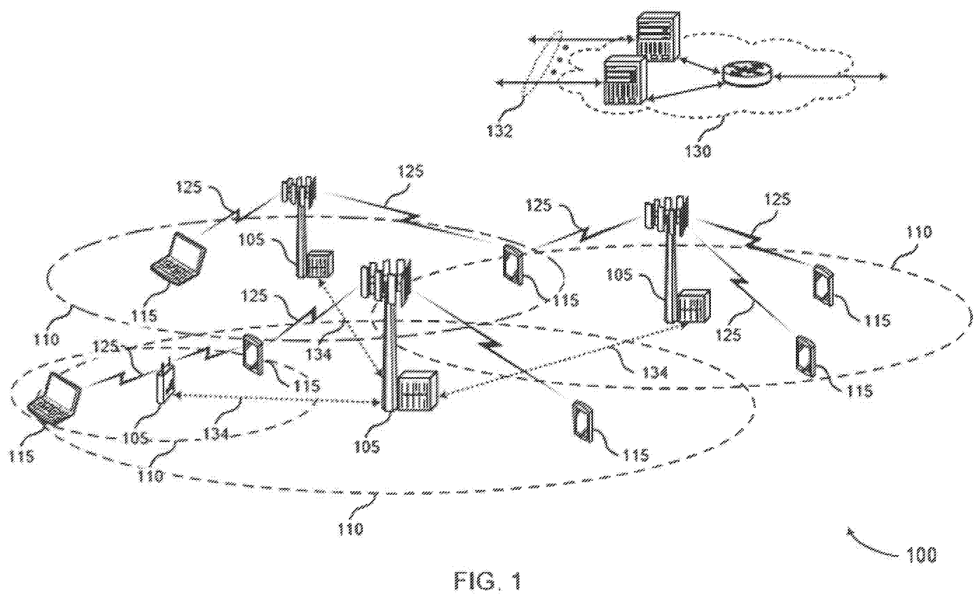

FIG. 1 illustrates an example of a wireless communications system 100 that supports techniques for cyclic redundancy check (CRC) of data with multiple channel coding schemes in accordance with aspects of the present disclosure. The wireless communications system 100 includes base stations 105, UEs 115, and a core network 130. In some examples, the wireless communications system 100 may be a Long Term Evolution (LTE) network, an LTE-Advanced (LTE-A) network, an LTE-A Pro network, or a New Radio (NR) network. In some cases, wireless communications system 100 may support enhanced broadband communications, ultra-reliable (e.g., mission critical) communications, low latency communications, or communications with low-cost and low-complexity devices.

Base stations 105 may wirelessly communicate with UEs 115 via one or more base station antennas. Base stations 105 described herein may include or may be referred to by those skilled in the art as a base transceiver station, a radio base station, an access point, a radio transceiver, a NodeB, an eNodeB (eNB), a next-generation NodeB or giga-NodeB (either of which may be referred to as a gNB), a Home NodeB, a Home eNodeB, or some other suitable terminology. Wireless communications system 100 may include base stations 105 of different types (e.g., macro or small cell base stations). The UEs 115 described herein may be able to communicate with various types of base stations 105 and network equipment including macro eNBs, small cell eNBs, gNBs, relay base stations, and the like.

Each base station 105 may be associated with a particular geographic coverage area 110 in which communications with various UEs 115 is supported. Each base station 105 may provide communication coverage for a respective geographic coverage area 110 via communication links 125, and communication links 125 between a base station 105 and a UE 115 may utilize one or more carriers. Communication links 125 shown in wireless communications system 100 may include uplink transmissions from a UE 115 to a base station 105, or downlink transmissions from a base station 105 to a UE 115. Downlink transmissions may also be called forward link transmissions while uplink transmissions may also be called reverse link transmissions.

The geographic coverage area 110 for a base station 105 may be divided into sectors making up a portion of the geographic coverage area 110, and each sector may be associated with a cell. For example, each base station 105 may provide communication coverage for a macro cell, a small cell, a hot spot, or other types of cells, or various combinations thereof. In some examples, a base station 105 may be movable and therefore provide communication coverage for a moving geographic coverage area 110. In some examples, different geographic coverage areas 110 associated with different technologies may overlap, and overlapping geographic coverage areas 110 associated with different technologies may be supported by the same base station 105 or by different base stations 105. The wireless communications system 100 may include, for example, a heterogeneous LTE/LTE-A/LTE-A Pro or NR network in which different types of base stations 105 provide coverage for various geographic coverage areas 110.

The term “cell” refers to a logical communication entity used for communication with a base station 105 (e.g., over a carrier), and may be associated with an identifier for distinguishing neighboring cells (e.g., a physical cell identifier (PCID), a virtual cell identifier (VCID)) operating via the same or a different carrier. In some examples, a carrier may support multiple cells, and different cells may be configured according to different protocol types (e.g., machine-type communication (MTC), narrowband Internet-of-Things (NB-IoT), enhanced mobile broadband (eMBB), or others) that may provide access for different types of devices. In some cases, the term “cell” may refer to a portion of a geographic coverage area 110 (e.g., a sector) over which the logical entity operates.

UEs 115 may be dispersed throughout the wireless communications system 100, and each UE 115 may be stationary or mobile. A UE 115 may also be referred to as a mobile device, a wireless device, a remote device, a handheld device, or a subscriber device, or some other suitable terminology, where the “device” may also be referred to as a unit, a station, a terminal, or a client. A UE 115 may also be a personal electronic device such as a cellular phone, a personal digital assistant (PDA), a tablet computer, a laptop computer, or a personal computer. In some examples, a UE 115 may also refer to a wireless local loop (WLL) station, an Internet of Things (IoT) device, an Internet of Everything (IoE) device, or an MTC device, or the like, which may be implemented in various articles such as appliances, vehicles, meters, or the like.

Some UEs 115, such as MTC or IoT devices, may be low cost or low complexity devices, and may provide for automated communication between machines (e.g., via Machine-to-Machine (M2M) communication). M2M communication or MTC may refer to data communication technologies that allow devices to communicate with one another or a base station 105 without human intervention. In some examples, M2M communication or MTC may include communications from devices that integrate sensors or meters to measure or capture information and relay that information to a central server or application program that can make use of the information or present the information to humans interacting with the program or application. Some UEs 115 may be designed to collect information or enable automated behavior of machines. Examples of applications for MTC devices include smart metering, inventory monitoring, water level monitoring, equipment monitoring, healthcare monitoring, wildlife monitoring, weather and geological event monitoring, fleet management and tracking, remote security sensing, physical access control, and transaction-based business charging.

Some UEs 115 may be configured to employ operating modes that reduce power consumption, such as half-duplex communications (e.g., a mode that supports one-way communication via transmission or reception, but not transmission and reception simultaneously). In some examples half-duplex communications may be performed at a reduced peak rate. Other power conservation techniques for UEs 115 include entering a power saving “deep sleep” mode when not engaging in active communications, or operating over a limited bandwidth (e.g., according to narrowband communications). In some cases, UEs 115 may be designed to support critical functions (e.g., mission critical functions), and a wireless communications system 100 may be configured to provide ultra-reliable communications for these functions.

In some cases, a UE 115 may also be able to communicate directly with other UEs 115 (e.g., using a peer-to-peer (P2P) or device-to-device (D2D) protocol). One or more of a group of UEs 115 utilizing D2D communications may be within the geographic coverage area 110 of a base station 105. Other UEs 115 in such a group may be outside the geographic coverage area 110 of a base station 105, or be otherwise unable to receive transmissions from a base station 105. In some cases, groups of UEs 115 communicating via D2D communications may utilize a one-to-many (1:M) system in which each UE 115 transmits to every other UE 115 in the group. In some cases, a base station 105 facilitates the scheduling of resources for D2D communications. In other cases, D2D communications are carried out between UEs 115 without the involvement of a base station 105.

Base stations 105 may communicate with the core network 130 and with one another. For example, base stations 105 may interface with the core network 130 through backhaul links 132 (e.g., via an S1, N2, N3, or other interface). Base stations 105 may communicate with one another over backhaul links 134 (e.g., via an X2, Xn, or other interface) either directly (e.g., directly between base stations 105) or indirectly (e.g., via core network 130).

The core network 130 may provide user authentication, access authorization, tracking, Internet Protocol (IP) connectivity, and other access, routing, or mobility functions. The core network 130 may be an evolved packet core (EPC), which may include at least one mobility management entity (MME), at least one serving gateway (S-GW), and at least one Packet Data Network (PDN) gateway (P-GW). The MME may manage non-access stratum (e.g., control plane) functions such as mobility, authentication, and bearer management for UEs 115 served by base stations 105 associated with the EPC. User IP packets may be transferred through the S-GW, which itself may be connected to the P-GW. The P-GW may provide IP address allocation as well as other functions. The P-GW may be connected to the network operators IP services. The operators IP services may include access to the Internet, Intranet(s), an IP Multimedia Subsystem (IMS), or a Packet-Switched (PS) Streaming Service.

At least some of the network devices, such as a base station 105, may include subcomponents such as an access network entity, which may be an example of an access node controller (ANC). Each access network entity may communicate with UEs 115 through a number of other access network transmission entities, which may be referred to as a radio head, a smart radio head, or a transmission/reception point (TRP). In some configurations, various functions of each access network entity or base station 105 may be distributed across various network devices (e.g., radio heads and access network controllers) or consolidated into a single network device (e.g., a base station 105).

Wireless communications system 100 may operate using one or more frequency bands, typically in the range of 300 megahertz (MHz) to 300 gigahertz (GHz). Generally, the region from 300 MHz to 3 GHz is known as the ultra-high frequency (UHF) region or decimeter band, since the wavelengths range from approximately one decimeter to one meter in length. UHF waves may be blocked or redirected by buildings and environmental features. However, the waves may penetrate structures sufficiently for a macro cell to provide service to UEs 115 located indoors. Transmission of UHF waves may be associated with smaller antennas and shorter range (e.g., less than 100 km) compared to transmission using the smaller frequencies and longer waves of the high frequency (HF) or very high frequency (VHF) portion of the spectrum below 300 MHz.

Wireless communications system 100 may also operate in a super high frequency (SHF) region using frequency bands from 3 GHz to 30 GHz, also known as the centimeter band. The SHF region includes bands such as the 5 GHz industrial, scientific, and medical (ISM) bands, which may be used opportunistically by devices that may be capable of tolerating interference from other users.

Wireless communications system 100 may also operate in an extremely high frequency (EHF) region of the spectrum (e.g., from 30 GHz to 300 GHz), also known as the millimeter band. In some examples, wireless communications system 100 may support millimeter wave (mmW) communications between UEs 115 and base stations 105, and EHF antennas of the respective devices may be even smaller and more closely spaced than UHF antennas. In some cases, this may facilitate use of antenna arrays within a UE 115. However, the propagation of EHF transmissions may be subject to even greater atmospheric attenuation and shorter range than SHF or UHF transmissions. Techniques disclosed herein may be employed across transmissions that use one or more different frequency regions, and designated use of bands across these frequency regions may differ by country or regulating body.

In some cases, wireless communications system 100 may utilize both licensed and unlicensed radio frequency spectrum bands. For example, wireless communications system 100 may employ License Assisted Access (LAA), LTE-Unlicensed (LTE-U) radio access technology, or NR technology in an unlicensed band such as the 5 GHz ISM band. When operating in unlicensed radio frequency spectrum bands, wireless devices such as base stations 105 and UEs 115 may employ listen-before-talk (LBT) procedures to ensure a frequency channel is clear before transmitting data. In some cases, operations in unlicensed bands may be based on a carrier aggregation configuration in conjunction with component carriers operating in a licensed band (e.g., LAA). Operations in unlicensed spectrum may include downlink transmissions, uplink transmissions, peer-to-peer transmissions, or a combination of these. Duplexing in unlicensed spectrum may be based on frequency division duplexing (FDD), time division duplexing (TDD), or a combination of both.

In some examples, base station 105 or UE 115 may be equipped with multiple antennas, which may be used to employ techniques such as transmit diversity, receive diversity, multiple-input multiple-output (MIMO) communications, or beamforming. For example, wireless communications system 100 may use a transmission scheme between a transmitting device (e.g., a base station 105) and a receiving device (e.g., a UE 115), where the transmitting device is equipped with multiple antennas and the receiving device is equipped with one or more antennas. MIMO communications may employ multipath signal propagation to increase the spectral efficiency by transmitting or receiving multiple signals via different spatial layers, which may be referred to as spatial multiplexing. The multiple signals may, for example, be transmitted by the transmitting device via different antennas or different combinations of antennas. Likewise, the multiple signals may be received by the receiving device via different antennas or different combinations of antennas. Each of the multiple signals may be referred to as a separate spatial stream, and may carry bits associated with the same data stream (e.g., the same codeword) or different data streams. Different spatial layers may be associated with different antenna ports used for channel measurement and reporting. MIMO techniques include single-user MIMO (SU-MIMO) where multiple spatial layers are transmitted to the same receiving device, and multiple-user MIMO (MU-MIMO) where multiple spatial layers are transmitted to multiple devices.

Beamforming, which may also be referred to as spatial filtering, directional transmission, or directional reception, is a signal processing technique that may be used at a transmitting device or a receiving device (e.g., a base station 105 or a UE 115) to shape or steer an antenna beam (e.g., a transmit beam or receive beam) along a spatial path between the transmitting device and the receiving device. Beamforming may be achieved by combining the signals communicated via antenna elements of an antenna array such that signals propagating at particular orientations with respect to an antenna array experience constructive interference while others experience destructive interference. The adjustment of signals communicated via the antenna elements may include a transmitting device or a receiving device applying certain amplitude and phase offsets to signals carried via each of the antenna elements associated with the device. The adjustments associated with each of the antenna elements may be defined by a beamforming weight set associated with a particular orientation (e.g., with respect to the antenna array of the transmitting device or receiving device, or with respect to some other orientation).

In one example, a base station 105 may use multiple antennas or antenna arrays to conduct beamforming operations for directional communications with a UE 115. For instance, some signals (e.g. synchronization signals, reference signals, beam selection signals, or other control signals) may be transmitted by a base station 105 multiple times in different directions, which may include a signal being transmitted according to different beamforming weight sets associated with different directions of transmission. Transmissions in different beam directions may be used to identify (e.g., by the base station 105 or a receiving device, such as a UE 115) a beam direction for subsequent transmission and/or reception by the base station 105.

Some signals, such as data signals associated with a particular receiving device, may be transmitted by a base station 105 in a single beam direction (e.g., a direction associated with the receiving device, such as a UE 115). In some examples, the beam direction associated with transmissions along a single beam direction may be determined based at least in in part on a signal that was transmitted in different beam directions. For example, a UE 115 may receive one or more of the signals transmitted by the base station 105 in different directions, and the UE 115 may report to the base station 105 an indication of the signal it received with a highest signal quality, or an otherwise acceptable signal quality. Although these techniques are described with reference to signals transmitted in one or more directions by a base station 105, a UE 115 may employ similar techniques for transmitting signals multiple times in different directions (e.g., for identifying a beam direction for subsequent transmission or reception by the UE 115), or transmitting a signal in a single direction (e.g., for transmitting data to a receiving device).

A receiving device (e.g., a UE 115, which may be an example of a mmW receiving device) may try multiple receive beams when receiving various signals from the base station 105, such as synchronization signals, reference signals, beam selection signals, or other control signals. For example, a receiving device may try multiple receive directions by receiving via different antenna subarrays, by processing received signals according to different antenna subarrays, by receiving according to different receive beamforming weight sets applied to signals received at a plurality of antenna elements of an antenna array, or by processing received signals according to different receive beamforming weight sets applied to signals received at a plurality of antenna elements of an antenna array, any of which may be referred to as “listening” according to different receive beams or receive directions. In some examples a receiving device may use a single receive beam to receive along a single beam direction (e.g., when receiving a data signal). The single receive beam may be aligned in a beam direction determined based at least in part on listening according to different receive beam directions (e.g., a beam direction determined to have a highest signal strength, highest signal-to-noise ratio, or otherwise acceptable signal quality based at least in part on listening according to multiple beam directions).

In some cases, the antennas of a base station 105 or UE 115 may be located within one or more antenna arrays, which may support MIMO operations, or transmit or receive beamforming. For example, one or more base station antennas or antenna arrays may be co-located at an antenna assembly, such as an antenna tower. In some cases, antennas or antenna arrays associated with a base station 105 may be located in diverse geographic locations. A base station 105 may have an antenna array with a number of rows and columns of antenna ports that the base station 105 may use to support beamforming of communications with a UE 115. Likewise, a UE 115 may have one or more antenna arrays that may support various MIMO or beamforming operations.

In some cases, wireless communications system 100 may be a packet-based network that operate according to a layered protocol stack. In the user plane, communications at the bearer or Packet Data Convergence Protocol (PDCP) layer may be IP-based. A Radio Link Control (RLC) layer may perform packet segmentation and reassembly to communicate over logical channels. A Medium Access Control (MAC) layer may perform priority handling and multiplexing of logical channels into transport channels. The MAC layer may also use hybrid automatic repeat request (HARQ) to provide retransmission at the MAC layer to improve link efficiency. In the control plane, the Radio Resource Control (RRC) protocol layer may provide establishment, configuration, and maintenance of an RRC connection between a UE 115 and a base station 105 or core network 130 supporting radio bearers for user plane data. At the Physical layer, transport channels may be mapped to physical channels.

In some cases, UEs 115 and base stations 105 may support retransmissions of data to increase the likelihood that data is received successfully. HARQ feedback is one technique of increasing the likelihood that data is received correctly over a communication link 125. HARQ may include a combination of error detection (e.g., using a cyclic redundancy check (CRC)), forward error correction (FEC), and retransmission (e.g., automatic repeat request (ARQ)). HARQ may improve throughput at the MAC layer in poor radio conditions (e.g., signal-to-noise conditions). In some cases, a wireless device may support same-slot HARQ feedback, where the device may provide HARQ feedback in a specific slot for data received in a previous symbol in the slot. In other cases, the device may provide HARQ feedback in a subsequent slot, or according to some other time interval.

Time intervals in LTE or NR may be expressed in multiples of a basic time unit, which may, for example, refer to a sampling period of Tₛ= 1/30,720,000 seconds. Time intervals of a communications resource may be organized according to radio frames each having a duration of 10 milliseconds (ms), where the frame period may be expressed as T_{f}=307,200 Tₛ. The radio frames may be identified by a system frame number (SFN) ranging from 0 to 1023. Each frame may include 10 subframes numbered from 0 to 9, and each subframe may have a duration of 1 ms. A subframe may be further divided into 2 slots each having a duration of 0.5 ms, and each slot may contain 6 or 7 modulation symbol periods (e.g., depending on the length of the cyclic prefix prepended to each symbol period). Excluding the cyclic prefix, each symbol period may contain 2048 sampling periods. In some cases, a subframe may be the smallest scheduling unit of the wireless communications system 100, and may be referred to as a transmission time interval (TTI). In other cases, a smallest scheduling unit of the wireless communications system 100 may be shorter than a subframe or may be dynamically selected (e.g., in bursts of shortened TTIs (sTTIs) or in selected component carriers using sTTIs).

In some wireless communications systems, a slot may further be divided into multiple mini-slots containing one or more symbols. In some instances, a symbol of a mini-slot or a mini-slot may be the smallest unit of scheduling. Each symbol may vary in duration depending on the subcarrier spacing or frequency band of operation, for example. Further, some wireless communications systems may implement slot aggregation in which multiple slots or mini-slots are aggregated together and used for communication between a UE 115 and a base station 105.

The term “carrier” refers to a set of radio frequency spectrum resources having a defined physical layer structure for supporting communications over a communication link 125. For example, a carrier of a communication link 125 may include a portion of a radio frequency spectrum band that is operated according to physical layer channels for a given radio access technology. Each physical layer channel may carry user data, control information, or other signaling. A carrier may be associated with a pre-defined frequency channel (e.g., an evolved universal mobile telecommunication system terrestrial radio access (E-UTRA) absolute radio frequency channel number (EARFCN)), and may be positioned according to a channel raster for discovery by UEs 115. Carriers may be downlink or uplink (e.g., in an FDD mode), or be configured to carry downlink and uplink communications (e.g., in a TDD mode). In some examples, signal waveforms transmitted over a carrier may be made up of multiple sub-carriers (e.g., using multi-carrier modulation (MCM) techniques such as orthogonal frequency division multiplexing (OFDM) or discrete Fourier transform spread OFDM (DFT-S-OFDM)).

The organizational structure of the carriers may be different for different radio access technologies (e.g., LTE, LTE-A, LTE-A Pro, NR). For example, communications over a carrier may be organized according to TTIs or slots, each of which may include user data as well as control information or signaling to support decoding the user data. A carrier may also include dedicated acquisition signaling (e.g., synchronization signals or system information, etc.) and control signaling that coordinates operation for the carrier. In some examples (e.g., in a carrier aggregation configuration), a carrier may also have acquisition signaling or control signaling that coordinates operations for other carriers.

Physical channels may be multiplexed on a carrier according to various techniques. A physical control channel and a physical data channel may be multiplexed on a downlink carrier, for example, using time division multiplexing (TDM) techniques, frequency division multiplexing (FDM) techniques, or hybrid TDM-FDM techniques. In some examples, control information transmitted in a physical control channel may be distributed between different control regions in a cascaded manner (e.g., between a common control region or common search space and one or more UE-specific control regions or UE-specific search spaces).

A carrier may be associated with a particular bandwidth of the radio frequency spectrum, and in some examples the carrier bandwidth may be referred to as a “system bandwidth” of the carrier or the wireless communications system 100. For example, the carrier bandwidth may be one of a number of predetermined bandwidths for carriers of a particular radio access technology (e.g., 1.4, 3, 5, 10, 15, 20, 40, or 80 MHz). In some examples, each served UE 115 may be configured for operating over portions or all of the carrier bandwidth. In other examples, some UEs 115 may be configured for operation using a narrowband protocol type that is associated with a predefined portion or range (e.g., set of subcarriers or RBs) within a carrier (e.g., “in-band” deployment of a narrowband protocol type).

In a system employing MCM techniques, a resource element may consist of one symbol period (e.g., a duration of one modulation symbol) and one subcarrier, where the symbol period and subcarrier spacing are inversely related. The number of bits carried by each resource element may depend on the modulation scheme (e.g., the order of the modulation scheme). Thus, the more resource elements that a UE 115 receives and the higher the order of the modulation scheme, the higher the data rate may be for the UE 115. In MIMO systems, a wireless communications resource may refer to a combination of a radio frequency spectrum resource, a time resource, and a spatial resource (e.g., spatial layers), and the use of multiple spatial layers may further increase the data rate for communications with a UE 115.

Devices of the wireless communications system 100 (e.g., base stations 105 or UEs 115) may have a hardware configuration that supports communications over a particular carrier bandwidth, or may be configurable to support communications over one of a set of carrier bandwidths. In some examples, the wireless communications system 100 may include base stations 105 and/or UEs 115 that support simultaneous communications via carriers associated with more than one different carrier bandwidth.

Wireless communications system 100 may support communication with a UE 115 on multiple cells or carriers, a feature which may be referred to as carrier aggregation or multi-carrier operation. A UE 115 may be configured with multiple downlink component carriers and one or more uplink component carriers according to a carrier aggregation configuration. Carrier aggregation may be used with both FDD and TDD component carriers.

With carrier aggregation, the number of the component carriers for uplink and the number of the component carrier for downlink may be different. For example, wireless communication system 100 may use two component carriers for downlink while wireless communication system 100 may use only one component carrier for uplink. For FDD, the frequency bands of the downlink component carriers may be different from the frequency bands of the uplink component carriers. For TDD, the frequency bands of the downlink component carriers may be the same as or different from the frequency bands of the uplink component carriers.

In some cases, wireless communications system 100 may utilize enhanced component carriers (eCCs). An eCC may be characterized by one or more features including wider carrier or frequency channel bandwidth, shorter symbol duration, shorter TTI duration, or modified control channel configuration. In some cases, an eCC may be associated with a carrier aggregation configuration or a dual connectivity configuration (e.g., when multiple serving cells have a suboptimal or non-ideal backhaul link). An eCC may also be configured for use in unlicensed spectrum or shared spectrum (e.g., where more than one operator is allowed to use the spectrum). An eCC characterized by wide carrier bandwidth may include one or more segments that may be utilized by UEs 115 that are not capable of monitoring the whole carrier bandwidth or are otherwise configured to use a limited carrier bandwidth (e.g., to conserve power).

In some cases, an eCC may utilize a different symbol duration than other component carriers, which may include use of a reduced symbol duration as compared with symbol durations of the other component carriers. A shorter symbol duration may be associated with increased spacing between adjacent subcarriers. A device, such as a UE 115 or base station 105, utilizing eCCs may transmit wideband signals (e.g., according to frequency channel or carrier bandwidths of 20, 40, 60, 80 MHz, etc.) at reduced symbol durations (e.g., 16.67 microseconds). A TTI in eCC may consist of one or multiple symbol periods. In some cases, the TTI duration (that is, the number of symbol periods in a TTI) may be variable.

Wireless communications system 100 may be an NR system that may utilize any combination of licensed, shared, and unlicensed spectrum bands, among others. The flexibility of eCC symbol duration and subcarrier spacing may allow for the use of eCC across multiple spectrums. In some examples, NR shared spectrum may increase spectrum utilization and spectral efficiency, specifically through dynamic vertical (e.g., across the frequency domain) and horizontal (e.g., across the time domain) sharing of resources.

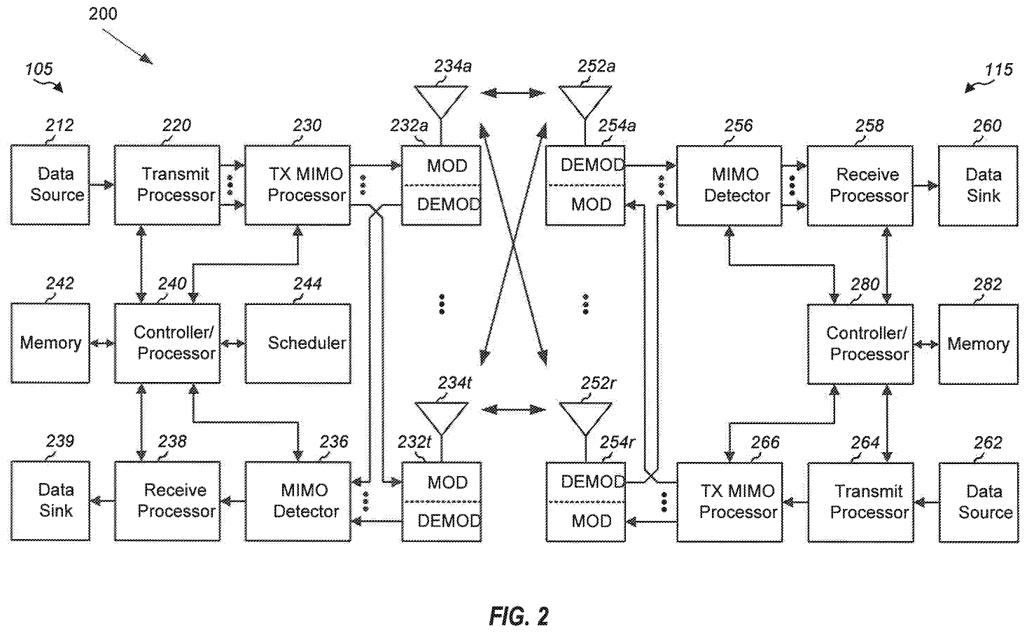

FIG. 2 shows a block diagram of a design of a base station 105 and a UE 115, which may be one of the base station and one of the UEs in FIG. 1. At the base station 105, a transmit processor 220 may receive data from a data source 212 and control information from a controller/processor 240. The control information may be for the PBCH, PCFICH, PHICH, PDCCH, EPDCCH, MPDCCH etc. The data may be for the PDSCH, etc. The transmit processor 220 may process (e.g., encode and symbol map) the data and control information to obtain data symbols and control symbols, respectively. The transmit processor 220 may also generate reference symbols, e.g., for the PSS, SSS, and cell-specific reference signal. A transmit (TX) multiple-input multiple-output (MIMO) processor 230 may perform spatial processing (e.g., precoding) on the data symbols, the control symbols, and/or the reference symbols, if applicable, and may provide output symbol streams to the modulators (MODs) 232a through 232t. Each modulator 232 may process a respective output symbol stream (e.g., for OFDM, etc.) to obtain an output sample stream. Each modulator 232 may further process (e.g., convert to analog, amplify, filter, and upconvert) the output sample stream to obtain a downlink signal. Downlink signals from modulators 232a through 232t may be transmitted via the antennas 234a through 234t, respectively.

At the UE 115, the antennas 252a through 252r may receive the downlink signals from the base station 105 and may provide received signals to the demodulators (DEMODs) 254a through 254r, respectively. Each demodulator 254 may condition (e.g., filter, amplify, downconvert, and digitize) a respective received signal to obtain input samples. Each demodulator 254 may further process the input samples (e.g., for OFDM, etc.) to obtain received symbols. A MIMO detector 256 may obtain received symbols from all the demodulators 254a through 254r, perform MIMO detection on the received symbols if applicable, and provide detected symbols. A receive processor 258 may process (e.g., demodulate, deinterleave, and decode) the detected symbols, provide decoded data for the UE 115 to a data sink 260, and provide decoded control information to a controller/processor 280.

On the uplink, at the UE 115, a transmit processor 264 may receive and process data (e.g., for the PUSCH) from a data source 262 and control information (e.g., for the PUCCH) from the controller/processor 280. The transmit processor 264 may also generate reference symbols for a reference signal. The symbols from the transmit processor 264 may be precoded by a TX MIMO processor 266 if applicable, further processed by the modulators 254a through 254r (e.g., for SC-FDM, etc.), and transmitted to the base station 105. At the base station 105, the uplink signals from the UE 115 may be received by the antennas 234, processed by the demodulators 232, detected by a MIMO detector 236 if applicable, and further processed by a receive processor 238 to obtain decoded data and control information sent by the UE 115. The processor 238 may provide the decoded data to a data sink 239 and the decoded control information to the controller/processor 240.

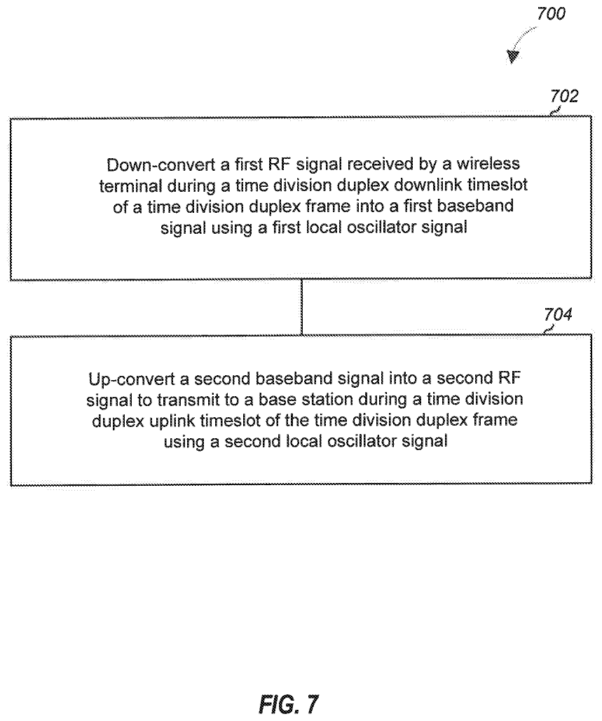

The controllers/processors 240 and 280 may direct the operation at the base station 105 and the UE 115, respectively. The controller/processor 240 and/or other processors and modules at the base station 105 may perform or direct the execution of various processes for the techniques described herein. The controllers/processor 280 and/or other processors and modules at the UE 115 may also perform or direct the execution of the functional blocks illustrated in FIG. 7 and/or other processes for the techniques described herein. The memories 242 and 282 may store data and program codes for the base station 105 and the UE 115, respectively. A scheduler 244 may schedule UEs for data transmission on the downlink and/or uplink.

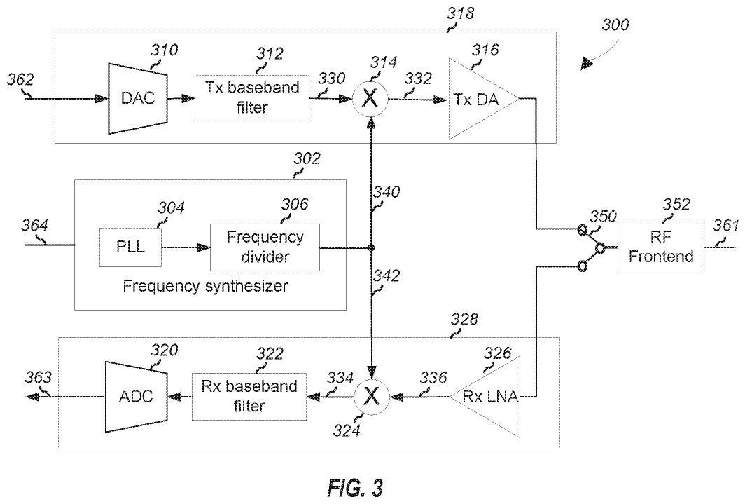

FIG. 3 is a block diagram illustrating an example circuit (shown as circuit 300) of a wireless device in a TDD system for up-conversion and down-conversion in accordance with aspects of the present disclosure. The circuit 300 may include a transmitter circuit portion and a receiver circuit portion that are in electrical communication. In some implementations, the transmitter circuit portion and the receiver circuit portion may be situated together yet in others may be stand-alone separate circuits. The circuit 300 may include additional components, including an oscillator to emit or source an oscillation signal. In some implementations, the oscillator may be or may contain a frequency synthesizer. In an aspect, the circuit 300 may, for example, be implemented as a portion of a wireless terminal (e.g., part of the modulator/demodulator 254 of UE 115 in FIG. 2). For example, RF signal input/output 361 of circuit 300 may couple to one or more of antennas 252a-252r, possibly via one or more additional components of modulator/demodulator 254. Transmit signal input 362 may couple to one or more outputs of TX MIMO processor 266, possibly via one or more additional components of modulator/demodulator 254. Likewise, receive signal output 363 may couple to one or more inputs of MIMO detector 256.

A frequency synthesizer 302 may generate a local oscillator signal. Thus the frequency synthesizer 302 may also be referred to as oscillator 302. The frequency synthesizer 302 may, for example, include a phase locked loop (PLL) 304 and a frequency divider 306 configured to generate local oscillator signals. The local oscillator signal can be used for up-conversion 340 and down-conversion 342. The local oscillator signal can fluctuate dynamically from a frequency perspective. In this manner, dynamic switching of signal frequency enables the oscillator 302 to source signals having varied frequencies (e.g., frequencies used for up conversion and frequencies used for down conversion). Accordingly, the PLL 304 and/or frequency divider 306 may be controlled to provide dynamic switching of frequencies according to aspects of the present disclosure. For example, frequency synthesizer 302 may be coupled to controller/processor 280 of FIG. 2 by control signal interface 364 for control with respect to changing frequencies of a oscillator signal in accordance with concepts of the present disclosure. By sourcing separate frequencies in variable frequency ranges for up/down conversions, the oscillator 302 can be used in a TDD environment to alternate between frequencies as a function of time (e.g., up convert one slot and down covert on a next slot, down convert on one slot and up convert on a next slot). Though it could be that oscillator 302 can also source oscillation signals in FDD or hybrid FDD/TDD operations too.

For transmission, a digital to analog converter (DAC) 310 in a transmitter circuit 318 may convert a baseband signal in digital form into a baseband signal in analog form. A Tx baseband filter 312 may remove high frequency components of the analog baseband signal to generate a smoother baseband signal 330. A mixer 314 may upconvert the baseband signal 330 into a RF signal 332 by mixing the baseband signal 330 with a local oscillator signal for up-conversion 340. A Tx driver amplifier (Tx DA) may amplify the RF signal 332 and may feed the amplified signal to a RF frontend 352 for transmission over the air using the antennas 252 in FIG. 2.

A switching circuit 350 is used in the illustrated example to controllably connect the RF frontend 352 with either the transmitter circuit 318 or a receiver circuit 328, such as when the circuit 300 is used in a TDD system. The switching circuit 350 may, for example, comprise a diplexer operating under control of controller/processor 280 of FIG. 2.

For reception, the RF frontend may feed a RF signal received over the air into a Rx low noise filter (Rx LNA) 326 in the receiver circuit 328. The Rx LNA 326 may amplify the received RF signal. A mixer 324 may down-convert the amplified RF signal 336 into a baseband signal 334 by mixing the RF signal 336 with a local oscillator signal for down-conversion 342. The Rx baseband filter 322 may remove high frequency components of the baseband signal 334, and an analog to digital converter (ADC) 320 may convert the baseband signal into digital signal for further processing in a digital domain.

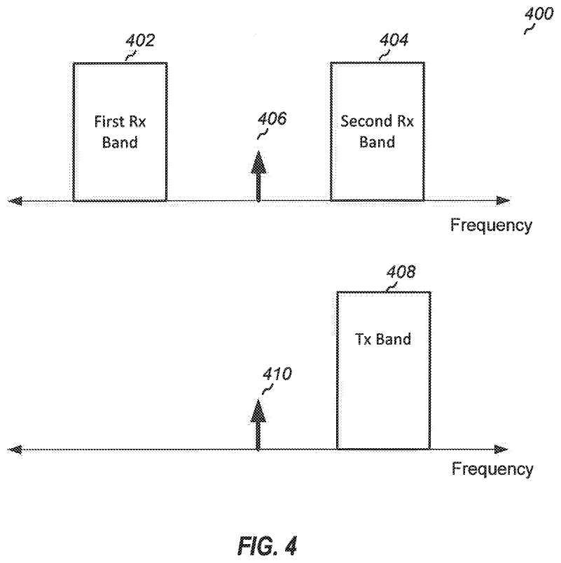

FIG. 4 illustrates, from a UE perspective, an example configuration of frequency band allocation 400 of a communication link in a TDD system. As shown, the frequency band allocation uses a fixed frequency (e.g., shown as oscillator signals 406 and 410 being at a same frequency) for a local oscillator signal for both up-conversion (e.g., up-conversion using oscillator signal 410) and down-conversion (e.g., down-conversion using oscillator signal 406) according to aspects of the present disclosure. In a typical TDD wireless system, where the uplink and downlink are separated by allocation of different time slots, the same frequency band is used for uplink communication and downlink communication. A UE in such a typical TDD wireless system may use a fixed frequency of the local oscillator signal for both up-conversion and down-conversion.

TDD communication according to aspects of the present disclosure may be implemented where the frequency band of uplink communication (Tx band from the UE perspective) and the frequency band of downlink communication (Rx band from the UE perspective) are different. For example, when a cellular communication system (e.g. wireless communication system 100 in FIG. 1) supports carrier aggregation, the communication link 125 in FIG. 1 may use multiple component carriers. In one aspect, a base station 105 in FIG. 1 may configure downlink of the communication link 125 with multiple component carriers and/or bandwidth parts in non-contiguous radio frequency bands. This is referred as non-contiguous carrier aggregation (NC-CA). At the same time, the base station 105 may configure only one component carrier for uplink of the communication link 125 or configure multiple contiguous component carriers in a single radio frequency band. In an aspect, first Rx Band 402 and second Rx Band 404 (Rx here being from the UE perspective) in FIG. 4 illustrate multiple component carriers in two non-contiguous radio frequency bands. Tx Band 408 (Tx here being from the UE perspective) illustrates one component carrier or multiple contiguous component carriers in a single radio frequency band.

As described above, a UE may use a fixed local oscillator frequency in a typical TDD wireless communication system where uplink and downlink use same frequency band. Such a UE configured with the Tx Band 408, the first Rx Band 402, and the second Rx Band 404 may set the frequency synthesizer 302 to generate the local oscillator signal in the same frequency for both up-conversion and down-conversion. Oscillator signal 406 in FIG. 4 illustrates the frequency of the local oscillator signal for down-conversion 342 in FIG. 3, and oscillator signal 410 in FIG. 4 illustrates the frequency of the local oscillator signal for up-conversion 340. It can be seen in the example of FIG. 4 that oscillator signals 406 and 410 are at a same frequency. This may be a simple approach when one frequency synthesizer is shared for both up-conversion and down-conversion, because the frequency synthesizer may generate the same local oscillator signals for both up-conversion and down-conversion. However, this configuration may be problematic with respect to energy leakage to adjacent frequency bands.

Wireless communication devices, such as UEs 115 in FIG. 1, may be configured in accordance with concepts of the present disclosure to minimize, reduce, and/or limit the amount of energy that leaks out of its assigned radio frequency bands. The wireless communication devices of aspects may thus minimize or otherwise reduce interferences to other radio communication devices using the adjacent bands. For example, 3GPP standards define the out-of-band emissions by a UE to be below −13 dBm. When using a fixed local oscillator frequency for both up-conversion and down-conversion, a UE may set the frequency of the down-conversion local oscillator signal 406 to be between the center frequencies of the first Rx band 402 and the center frequency of the second Rx band 404 as shown in FIG. 4. In this example, the frequency of the down-conversion local oscillator signal 410 is the same as the frequency of the down-conversion local oscillator signal 406. The frequency of the down-conversion local oscillator signal 410 is out of the Tx band 408. Energy from the local oscillator signal at the frequency of oscillator signal 410 may thus contribute to the out of band emission when the UE transmits the up-converted RF signal. The UE may, for example, fail to exhibit desirable out-of-band emission levels (e.g., exceed an out-of-band emission threshold or requirement).

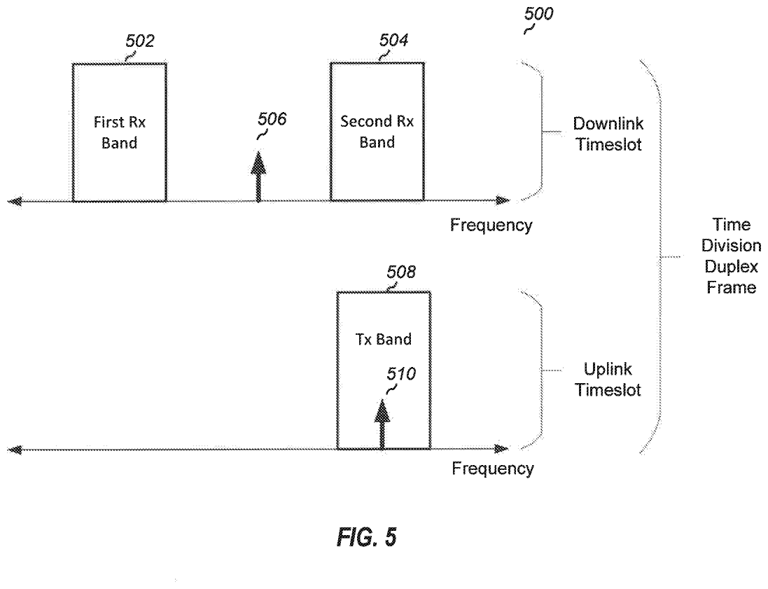

FIG. 5 illustrates, from a UE perspective, an example configuration of frequency band allocation 500 of a communication link in a TDD system according to aspects of the present disclosure. In the example of FIG. 5, dynamic switching of frequencies for a local oscillator signal is provided in accordance with aspects of the present disclosure. The dynamic switching of local oscillator frequencies may be used according to aspects to address problems with respect to energy leakage described above. In the configuration of FIG. 5, during the timeslot for downlink communication, a UE 115 may set the frequency of the local oscillator signal 506 to be between the center frequencies of the first Rx band 502 and the center frequency of the second Rx band 504 for down-conversion. Differently from the configuration of FIG. 4, during the timeslot for uplink communication, the UE 115 in the configuration of FIG. 5 may further set the frequency of the local oscillator signal 510 within Tx band 508 for up-conversion. This may make meeting the out-of-band emission requirement easier compared to the configuration of 400 in FIG. 4.

In providing dynamic switching of frequencies for a local oscillator as shown in FIG. 5, the frequency synthesizer 302 in FIG. 3 in the UE 115 may switch from generation of a first local oscillator signal with the frequency of local oscillator signal 506 to generation of a second local oscillator signal with the frequency of local oscillator signal 510 between reception of the first RF signal and transmission of the second RF signal. The frequency synthesizer 302 may also switch from generation of the second local oscillator signal with the frequency of local oscillator signal 510 to generation of the first local oscillator signal with the frequency of local oscillator signal 506 between transmission of the second RF signal and reception of the second RF signal. The frequency synthesizer 302 may switch generation of the first local oscillator signal and the second local oscillator signal by changing frequency of signals generated by the PLL 304. Additionally or alternatively, The frequency synthesizer 302 may switch generation of the first local oscillator signal and the second local oscillator signal by changing configuration of the frequency divider 306. For example, in accordance with aspects, controller/processor 280 may provide one or more control signals to frequency synthesizer 302 in correspondence with the downlink/uplink timeslot timing (e.g., between the downlink timeslots and uplink timeslots of TDD frames) of the TDD operation for the communication link. The control signals may, for example, control the timing of changing the local oscillator signal frequency and the particular frequency to which the local oscillator signal is to be changed, such as based upon the controller/processor having information regarding the timing of TTD timeslots and the frequencies of the received and transmitted RF signals.

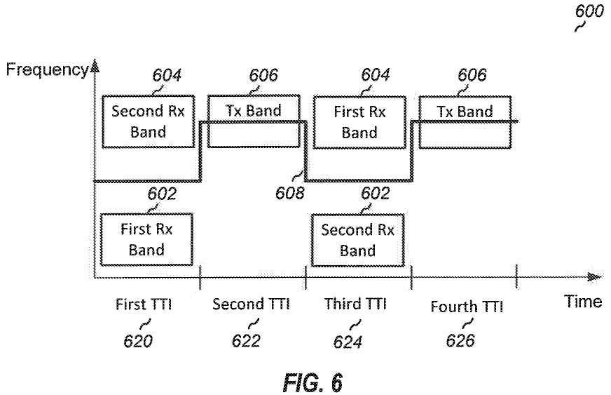

FIG. 6 illustrates another example configuration of frequency band allocation of a communication link in a TDD system according to aspects of the present disclosure. Frequency band allocation 600 may comprise a frequency band allocation of a communication link 125 of FIG. 1 in a TDD system. The example of FIG. 6 is configured with dynamic switching of frequencies for a local oscillator signal according to aspects of the present disclosure. In FIG. 6, the x axis represents time and the y axis represents frequency. During the first transmission time interval (TTI) 620 (e.g., a first downlink timeslot), a UE 115 receives RF signal from a base station 105 using multiple component carriers in non-contiguous frequency bands including first Rx band 602 and second Rx band 604. During the first TTI 620, the frequency synthesizer 302 may generate local oscillator signal 608 with a frequency between the center frequencies of the first Rx band 602 and the second Rx band 604. During the second TI 622 (e.g., a first uplink timeslot), the frequency synthesizer 302 may change the frequency of the local oscillator signal 608 to within the Tx band 606. Changing the frequency of the local oscillator signal 608 may occur when switching between receiving operation and transmitting operation occurs. During the third TTI 624 (e.g., a second downlink timeslot), the frequency synthesizer 302 may again change the frequency of the local oscillator signal 608 to the frequency of the local oscillator signal during the first TTI 620. And during the fourth TTI 626 (e.g., a second uplink timeslot), the frequency synthesizer 302 may again change the frequency of the local oscillator signal 608 to the frequency of the local oscillator signal during the second TTI 622. Similar operations may continue as the UE 115 communicates with a base station 105 using first Rx band 602, second Rx band 604, and Tx band 606.

FIG. 7 is a flow diagram illustrating example blocks executed at a UE for dynamic switching of local oscillator signal frequency for up-conversion and down-conversion according to aspects of the present disclosure. Operation at block 702 of exemplary flow 700 provides for down-converting a first RF signal received by a wireless terminal during a TDD downlink timeslot into a first baseband signal using a first local oscillator signal. For example, a receiver circuit of the wireless terminal may down-convert a first RF signal received by the wireless terminal into a first baseband signal using a first local oscillator signal from a local oscillator signal source during a TDD downlink timeslot of a TDD downlink/uplink frame. The first RF signal may comprise a plurality of non-contiguous radio frequency bands. In accordance with aspects of the present disclosure, the frequency of the first local oscillator signal is between center frequencies of the plurality of non-contiguous radio frequency bands. In an aspect, reception and transmission may alternate in time by a UE in a TDD system.

Operation at block 704 provides for up-converting a second baseband signal into a second RF signal to transmit to a base station during a TDD uplink timeslot using a second local oscillator signal. For example, a transmitter circuit of the wireless terminal may upconvert a second baseband signal into a second RF signal to transmit to a base station using a second local oscillator signal from the local oscillator signal source during a TDD uplink timeslot of a same TDD downlink/uplink frame the first RF signals is received in. The second RF signal may comprise a single frequency band. In accordance with aspects of the present disclosure, the frequency of the second local oscillator signal is within the single frequency band of the second RF signal. The local oscillator signal source may comprise a frequency synthesizer coupled to the receiver circuit and the transmitter circuit, generating the first local oscillator signal and the second local oscillator signal. The frequency synthesizer may comprise a phase locked loop (PLL) and a frequency divider.

Although examples have been provided with respect to implementation of local oscillator frequency switching at a UE, that the concepts disclosed herein may be applied to various other devices, including, e.g., a base station and relay. For example, a relay that acts as a UE towards a donor base station in a connection link while serving other UEs as a base station in another communication link may adopt the methods and techniques in the current disclosure.

Also, although examples have been provided with respect to implementation of switching between two frequencies of local oscillator signal, the method and technique described in the current disclosure may be applied when local oscillator signal switches among more than two frequencies. For example, a UE in a TDD system may use two Rx channels using different frequency bands that are time divided and use a Tx channel using another frequency band different form the two Rx channels. The frequencies of the local oscillator signal of the UE implementing methods and techniques in the current disclosure may switch among three different frequencies that are selected for two Rx channels and the Tx channel respectively.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The functional blocks and modules in FIG. 7 may comprise processors, electronics devices, hardware devices, electronics components, logical circuits, memories, software codes, firmware codes, etc., or any combination thereof.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Skilled artisans will also readily recognize that the order or combination of components, methods, or interactions that are described herein are merely examples and that the components, methods, or interactions of the various aspects of the present disclosure may be combined or performed in ways other than those illustrated and described herein.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the disclosure herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. Computer-readable storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, a connection may be properly termed a computer-readable medium. For example, if the software is transmitted from a website, server, or other remote source using a coaxial cable, fiber optic cable, twisted pair, or digital subscriber line (DSL), then the coaxial cable, fiber optic cable, twisted pair, or DSL, are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

As used herein, including in the claims, the term “and/or,” when used in a list of two or more items, means that any one of the listed items can be employed by itself, or any combination of two or more of the listed items can be employed. For example, if a composition is described as containing components A, B, and/or C, the composition can contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (i.e., A and B and C) or any of these in any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A wireless terminal in time division duplex (TDD) system comprising:
a receiver circuit configured to down-convert a first radio frequency (RF) signal received by the wireless terminal during a TDD downlink timeslot of a TDD frame into a first baseband signal using a first local oscillator signal from a local oscillator signal source, wherein the local oscillator signal source comprises a phase locked loop (PLL) and a frequency divider, and wherein the first RF signal comprises a plurality of non-contiguous radio frequency bands, and wherein the plurality of non-contiguous radio frequency bands are configured with non-contiguous carrier aggregation;
a transmitter circuit configured to upconvert a second baseband signal into a second RF signal to transmit to a base station during a TDD uplink timeslot of the TDD frame using a second local oscillator signal from the local oscillator signal source, wherein the second RF signal comprises a single frequency band; and
a controller configured to:
provide, based on timing information of the TDD downlink timeslot, a first control signal to the local oscillator signal source individually controlling a frequency of the PLL and a configuration of the frequency divider, wherein the first control signal individually controlling the frequency and configuration controls generation of the first local oscillator signal such that the first local oscillator signal is between center frequencies of two of the plurality of non-contiguous radio frequency bands; and
provide, based on timing information of the TDD uplink timeslot, a second control signal to the local oscillator signal source individually controlling the frequency of the PLL and the configuration of the frequency divider, wherein the second control signal individually controlling the frequency and configuration controls generation of the second local oscillator signal such that the second local oscillator signal is within the single frequency band, and wherein the controller switches between generation of the first local oscillator signal and generation of the second local oscillator signal between reception of the first RF signal and transmission of the second RF signal within the TDD frame by individually controlling frequency of signals generated by the PLL and the configuration of the frequency divider.

2. The wireless terminal of claim 1, wherein a frequency of the first local oscillator signal is between center frequencies of the plurality of non-contiguous radio frequency bands, and wherein a frequency of the second local oscillator signal is within the single frequency band of the second RF signal.

3. (canceled)

4. The wireless terminal of claim 2, wherein the single frequency band of the second RF signal corresponds to one of the plurality of non-contiguous radio frequency bands of the first RF signal.

5. The wireless terminal of claim 1, wherein the local oscillator signal source comprises a frequency synthesizer coupled to the receiver circuit and the transmitter circuit, generating the first local oscillator signal and the second local oscillator signal.

6. (canceled)

7. (canceled)

8. (canceled)

9. The wireless terminal of claim 1, wherein the local oscillator signal source switches from generation of the first local oscillator signal to generation of the second local oscillator signal between reception of the first RF signal and transmission of the second RF signal, and wherein the local oscillator signal source switches from generation of the second local oscillator signal to generation of the first local oscillator signal between transmission of the second RF signal and reception of a second instance of the first RF signal.

10. (canceled)

11. A method for time division duplex (TDD) wireless communication comprising:
down-converting, by a receiver circuit of a wireless terminal, a first radio frequency (RF) signal received by the wireless terminal during a TDD downlink timeslot of a TDD frame into a first baseband signal using a first local oscillator signal from a local oscillator signal source, wherein the first RF signal comprises a plurality of non-contiguous radio frequency bands, and wherein the plurality of non-contiguous radio frequency bands are configured with non-contiguous carrier aggregation, wherein the local oscillator signal source comprises a phase locked loop (PLL) and a frequency divider;
upconverting, by a transmitter circuit of the wireless terminal, a second baseband signal into a second RF signal to transmit to a base station during a TDD uplink timeslot of the TDD frame using a second local oscillator signal from the local oscillator signal source, wherein the second RF signal comprises a single frequency band;
providing, by a controller of the wireless terminal to the local oscillator signal source during the down conversion, a first control signal individually controlling a frequency of the PLL and a configuration of the frequency divider so as to control generation of the first local oscillator signal such that the first local oscillator signal is between center frequencies of two of the plurality of non-contiguous radio frequency bands; and
providing, by the controller to the local oscillator signal source during the up conversion, a second control signal individually controlling the frequency of the PLL and the configuration of the frequency divider so as to control generation of the second local oscillator signal such that the second local oscillator signal is within the single frequency band, and wherein the controller switches between generation of the first local oscillator signal and generation of the second local oscillator signal between reception of the first RF signal and transmission of the second RF signal within the TDD frame by individually controlling frequency of signals generated by the PLL and the configuration of the frequency divider.

12. The method of claim 11, wherein a frequency of the first local oscillator signal is between center frequencies of the plurality of non-contiguous radio frequency bands, and wherein the second RF signal comprises a single frequency band and a frequency of the second local oscillator signal is within the single frequency band of the second RF signal.

13. (canceled)

14. The method of claim 12, wherein the single frequency band of the second RF signal corresponds to one of the plurality of non-contiguous radio frequency bands of the first RF signal.

15. The method of claim 11, further comprising:
generating, by a frequency synthesizer of the local oscillator signal source, the first local oscillator signal and the second local oscillator signal.

16. (canceled)

17. (canceled)

18. (canceled)

19. The method of claim 11, further comprising:
switching from generation of the first local oscillator signal to generation of the second local oscillator signal between reception of the first RF signal and transmission of the second RF signal, and
switching from generation of the second local oscillator signal to generation of the first local oscillator signal between transmission of the second RF signal and reception of a next instance of the first RF signal.

20. (canceled)

21. An article of manufacture comprising:
a non-transitory computer-readable medium having stored therein instructions executable by a processor of a wireless terminal in time division duplex (TDD) wireless communication to
provide a first local oscillator signal from a local oscillator signal source to down-convert a first RF signal received by the wireless terminal during a TDD downlink timeslot of a TDD frame into a first baseband signal, wherein the first RF signal comprises a plurality of non-contiguous radio frequency bands, and wherein the plurality of non-contiguous radio frequency bands are configured with non-contiguous carrier aggregation, wherein the local oscillator signal source comprises a phase locked loop (PLL) and a frequency divider; and
provide a second local oscillator signal from the local oscillator signal source to upconvert a second baseband signal into a second RF signal to transmit to a base station during a TDD uplink timeslot of the TDD frame, wherein the second RF signal comprises a single frequency band;
provide, based on timing information of the TDD downlink timeslot, a first control signal to the local oscillator signal source individually controlling a frequency of the PLL and a configuration of the frequency divider, wherein the first control signal individually controlling the frequency and configuration controls generation of the first local oscillator signal such that the first local oscillator signal is between center frequencies of two of the plurality of non-contiguous radio frequency bands; and
provide, based on timing information of the TDD uplink timeslot, a second control signal to the local oscillator signal source individually controlling the frequency of the PLL and the configuration of the frequency divider, wherein the second control signal individually controlling the frequency and configuration controls generation of the second local oscillator signal such that the second local oscillator signal is within the single frequency band, and wherein the controller switches between generation of the first local oscillator signal and generation of the second local oscillator signal between reception of the first RF signal and transmission of the second RF signal within the TDD frame by individually controlling frequency of signals generated by the PLL and the configuration of the frequency divider.

22. The article of claim 21, wherein a frequency of the first local oscillator signal is between center frequencies of the plurality of non-contiguous radio frequency bands, and wherein the second RF signal comprises a single frequency band and a frequency of the second local oscillator signal is within the single frequency band of the second RF signal.

23. The article of claim 21, wherein the local oscillator signal source comprises a frequency synthesizer configured to generate the first local oscillator signal and the second local oscillator signal.

24. (canceled)

25. (canceled)

26. (canceled)

27. The article of claim 24, further comprising the non-transitory computer-readable medium having stored therein instructions to:
make the frequency synthesizer switch from generation of the first local oscillator signal to generation of the second local oscillator signal between reception of the first RF signal and transmission of the second RF signal, and
make the frequency synthesizer switch from generation of the second local oscillator signal to generation of the first local oscillator signal between transmission of the second RF signal and reception of a second instance of the first RF signal.

28. (canceled)

29. The article of claim 22, wherein the single frequency band of the second local oscillator signal corresponds to one of the plurality of non-contiguous radio frequency bands of the first local oscillator signal.
